(19) United States
(12) Patent Application Publication
(10) Pub. No.: US 2008/0102637 A1
(43) Pub. Date: May 1, 2008

(54) Method and semiconductor structure for reliability characterization

(75) Inventors: Jun Zhai, Sunnyvale, CA (US); Richard C. Blish, Saratoga, CA (US); Fei Wang, San Jose, CA (US)

Correspondence Address: FARJAMI & FARJAMI LLP, 26522 LA ALAMEDA AVENUE, SUITE 360, MISSION VIEJO, CA, 92691, US

(73) Assignee: Advanced Micro Devices, Inc.

(21) Appl. No.: 11/590,183

(22) Filed: Oct. 31, 2006

(51) Int. Cl. H01L 21/311

(52) U.S. Cl. 438/700

(57) ABSTRACT

According to one exemplary embodiment, a method for characterizing a reliability of a semiconductor structure includes forming a recess in a first dielectric layer in the semiconductor structure; filling the recess with a sacrificial material; removing the sacrificial material thereby causing an intentional defect with known characteristics to aid in a characterizing the reliability of the semiconductor structure.

### 1. TECHNICAL FIELD

The present invention is generally in the field of semiconductors. More particularly, the invention is in the field of reliability characterization of semiconductor structures.

### 2. BACKGROUND ART

Reliability of semiconductor structures are often dependent on reliability of dielectric layers. Dielectric layers, such as interlayer dielectric layers (“ILDs”), are typically used in semiconductor structures to provide insulation between different layers, e.g., metal layers, included in the semiconductor structures. These dielectric layers, however, are typically brittle and tend to adhere poorly with adjacent layers, such as etch stop layers. As a result, defects existing in the dielectric layers, such as voids, may result in extended or additional defects, i.e. may spread or “propagate,” when the semiconductor structures are exposed to various temperatures and mechanical stresses, ultimately causing the semiconductor structures to fail. Therefore, it is critical to properly characterize the reliability of semiconductor structures by, for example, determining the propagation rates of such defects in dielectric layers to accurately predict the life of semiconductor structures.

However, determining the propagation rates of defects using conventional semiconductor test structures is difficult because, for example, the initial locations, sizes, and shapes of such defects are typically unknown. Once a defect in a dielectric layer of a conventional semiconductor test structure causes additional defects, i.e. spreads or propagates, the initial location and other characteristics of the defect cannot be determined. Since it is difficult to determine the characteristics, e.g. the location, size, and shape, of the initial defect, the reliability of the semiconductor structure and, in particular, the reliability of dielectric layers in those structures, cannot be easily understood, characterized or improved.

### SUMMARY

A method and semiconductor structure for reliability characterization, substantially as shown in and/or described in connection with at least one of the figures, as set forth more completely in the claims.

### BRIEF DESCRIPTION OF THE DRAWINGS

FIG. 1 shows a flowchart illustrating the steps taken to implement an embodiment of the invention.

FIG. 2A illustrates an exemplary semiconductor structure after completion of an initial step of the flowchart of FIG. 1.

FIG. 2B illustrates an exemplary semiconductor structure after completion of an intermediate step of the flowchart of FIG. 1.

FIG. 2C illustrates an exemplary semiconductor structure after completion of an intermediate step of the flowchart of FIG. 1.

FIG. 2D illustrates an exemplary semiconductor structure after completion of an intermediate step of the flowchart of FIG. 1.

FIG. 2E illustrates an exemplary semiconductor structure after completion of an intermediate step of the flowchart of FIG. 1.

FIG. 3 illustrates an exemplary mask layer including exemplary recess openings utilized to implement one embodiment of the invention.

FIG. 4 illustrates an exemplary system utilized for testing one or more exemplary semiconductor structures in accordance with one embodiment of the invention.

### DETAILED DESCRIPTION OF THE INVENTION

The present invention is directed to method and semiconductor structure for reliability characterization. The following description contains specific information pertaining to the implementation of the present invention. One skilled in the art will recognize that the present invention may be implemented in a manner different from that specifically discussed in the present application. Moreover, some of the specific details of the invention are not discussed in order not to obscure the invention.

The drawings in the present application and their accompanying detailed description are directed to merely exemplary embodiments of the invention. To maintain brevity, other embodiments of the present invention are not specifically described in the present application and are not specifically illustrated by the present drawings.

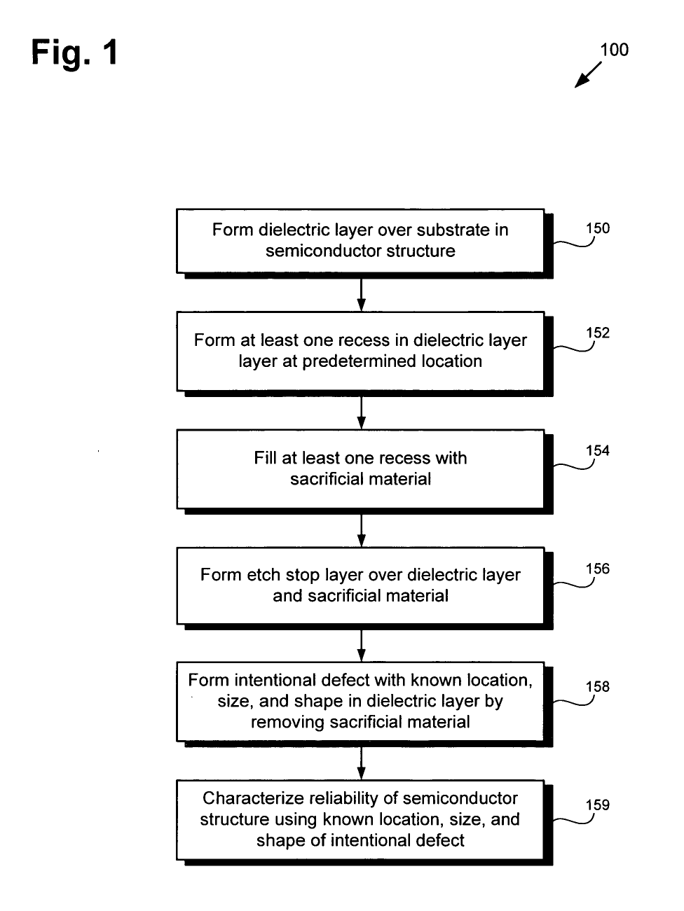

FIG. 1 shows flowchart 100, which illustrates an exemplary method according to one embodiment of the invention. Certain details and features have been left out of flowchart 100 that are apparent to a person of ordinary skill in the art. For example, a step may consist of one or more substeps or may involve specialized equipment or materials, as known in the art. Steps 150 through 159 indicated in flowchart 100 are sufficient to describe one embodiment of the invention. Other embodiments of the invention may utilize steps different from those shown in flowchart 100.

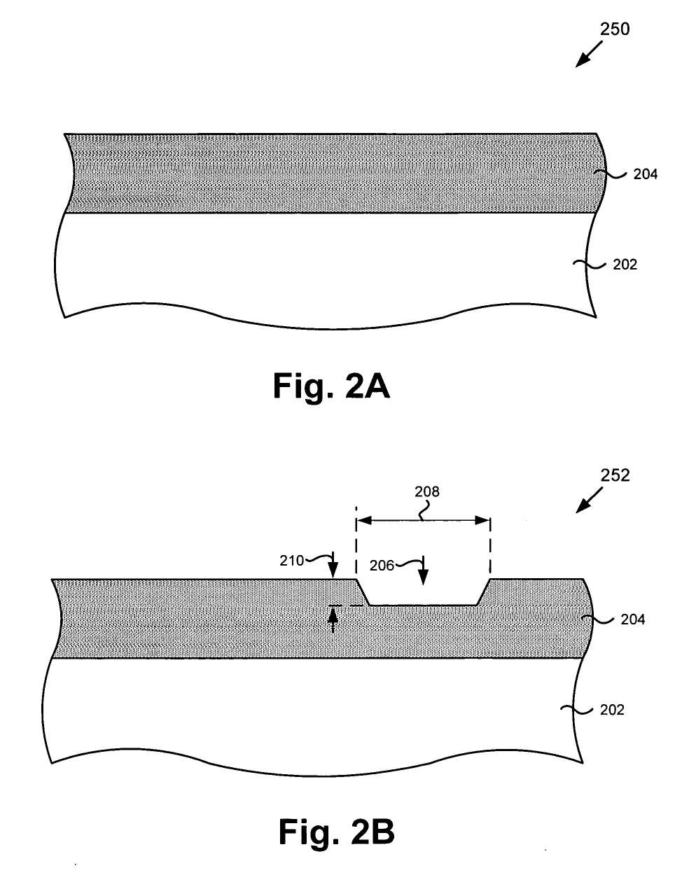

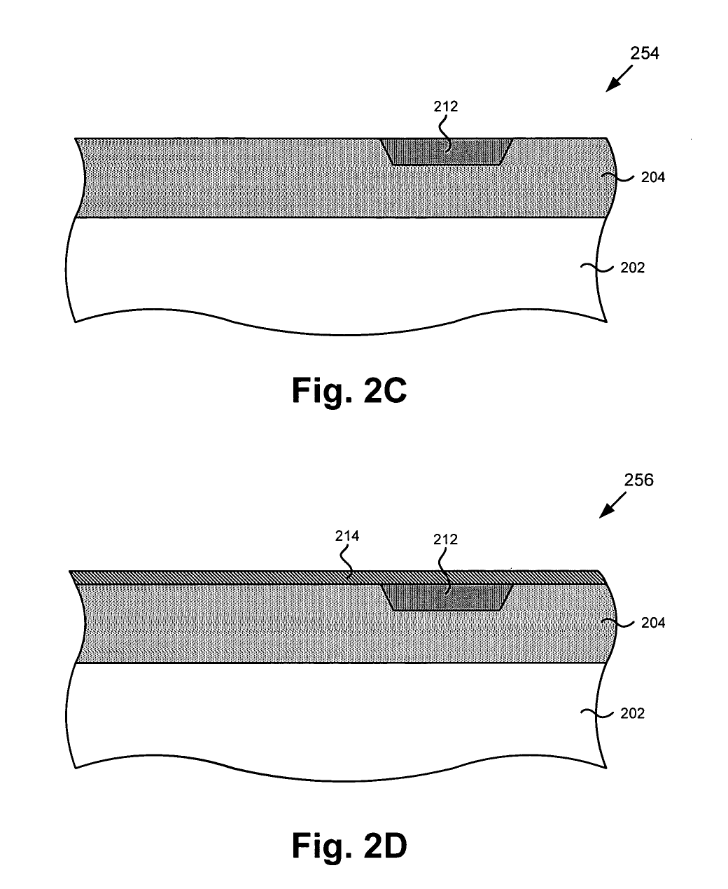

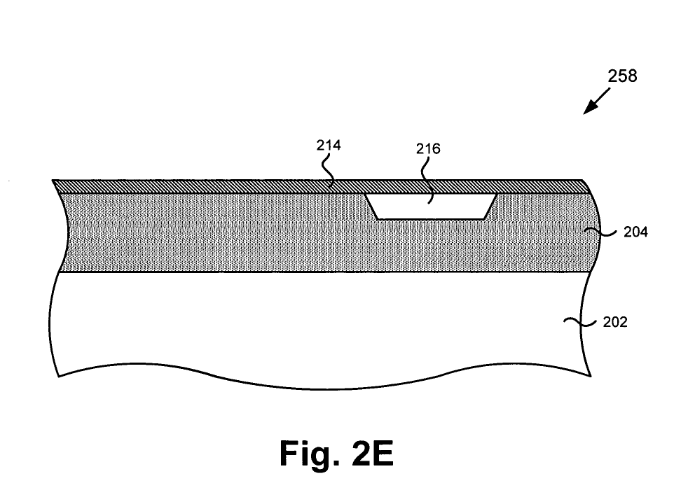

Moreover, structures 250 through 258 in FIGS. 2A through 2E illustrate the result of performing steps 150 through 158 of flowchart 100, respectively. For example, structure 250 shows a semiconductor structure after processing step 150, structure 252 shows a semiconductor structure after processing step 152, structure 254 shows a semiconductor structure after processing step 154, and so on.

Referring to step 150 in FIG. 1 and semiconductor structure 250 in FIG. 2A, at step 150 of flowchart 100, dielectric layer 204 is formed over substrate 202 in semiconductor structure 250. Dielectric layer 204 can be formed, for example, by using a chemical vapor deposition process (“CVD”) or by using other processes that are known in the art. For example, dielectric layer 204 can be a low-k interlayer dielectric layer (“ILD”) and can comprise a low-k carbon doped oxide material or other suitable dielectric material.

Referring to step 152 in FIG. 1 and semiconductor structure 252 in FIG. 2B, at step 152 of flowchart 100, recess 206 is formed in dielectric layer 204 at a predetermined location in semiconductor structure 252. As shown in FIG. 2B, for example, recess 206 has a size defined by a width, e.g., width 208, a depth, e.g., depth 210, and a length (not shown in FIG. 2B). In the embodiment shown in FIG. 2B, recess 206 has a rectangular shape as seen from a top view (not shown) of recess 206. However, in other embodiments, recess 206 can have a different shape. Recess 206 can be formed, for example, by forming a mask layer over dielectric layer 204 that includes an opening at a location where recess 206 is desired and by using a dual damascene process or other appropriate etching process that is known in the art. Although the embodiment in FIG. 2B shows one recess, i.e., recess 206, other embodiments can include a number of recesses having various shapes and sizes.

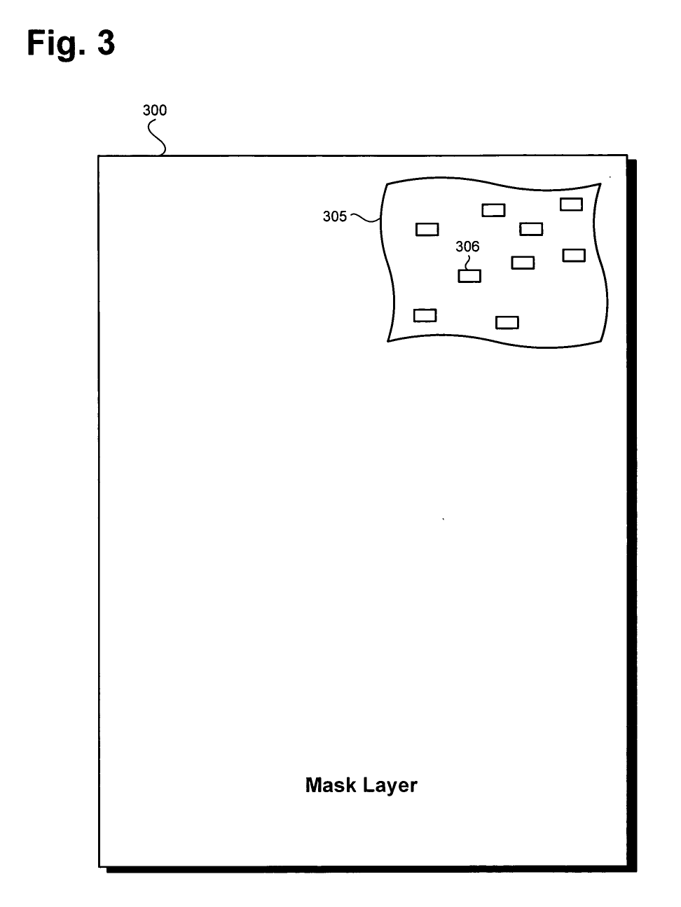

FIG. 3 shows a top view of mask layer 300 which can be formed over dielectric layer 204 formed at step 150 to pattern recess 206 formed at step 152, in accordance with one embodiment of the invention. In particular, recess opening 306 in FIG. 3 corresponds to recess 206 in FIG. 2B. As shown in FIG. 3, portion 305 of mask layer 300 includes a number of recess openings which can be used to form recesses, such as recess 206 shown in FIG. 2B, at predetermined locations in a dielectric layer of the semiconductor structure.

Referring to step 154 in FIG. 1 and semiconductor structure 254 in FIG. 2C, at step 154 of flowchart 100, recess 206 in FIG. 2B is filled with sacrificial material 212. Sacrificial material 212, for example, can be a decomposable polymer, such as a copolymer of butylnorbornene and triethoxysilyl norbornene, and can be applied using spin coating methods known in the art. The decomposition temperature of sacrificial material 212, i.e., the temperature at which sacrificial material 212 decomposes, should be greater than the formation temperature of dielectric layer 204, i.e., the temperature at which dielectric layer 204 is formed, in order to prevent premature decomposition of sacrificial material 212.

Referring to step 156 in FIG. 1 and semiconductor structure 256 in FIG. 2D, at step 156 of flowchart 100, etch stop layer 214 is formed over dielectric layer 204 and sacrificial material 212. Thus, as shown in FIG. 2D, sacrificial material 212 is situated at the interface between etch stop layer 214 and dielectric layer 204. In another embodiment of the invention, additional layers (e.g., additional dielectric layers) may be formed on dielectric layer 204 and sacrificial material 212 prior to forming the etch stop layer over dielectric layer 204 and sacrificial material 212. In such an embodiment, sacrificial material 212 is situated within dielectric layer 204 such that sacrificial material 212 is not situated at the interface between etch stop layer 214 and dielectric layer 204.

Referring to step 158 in FIG. 1 and semiconductor structure 258 in FIG. 2E, at step 158 of flowchart 100, intentional defect 216 with known characteristics, e.g., known location, size, and shape, is formed by removing sacrificial material 212 in FIG. 2D, thus creating a void at the interface between etch stop layer 214 and dielectric layer 204. Sacrificial material 212 can be removed, for example, by decomposing sacrificial material 212 by performing an adequate heating process on semiconductor structure 256 in FIG. 2D. In the abovementioned embodiment wherein the sacrificial material is situated within the dielectric layer such that the sacrificial material is not situated at the interface between etch stop layer 214 and dielectric layer 204, the intentional defect, i.e., the void, is formed within dielectric layer 204 and is therefore not situated at the interface between etch stop layer 214 and dielectric layer 204.

Thus, the invention enables the formation of intentional defects with known characteristics in a semiconductor structure. For example, the location of an intentional defect to be formed in the semiconductor structure of the invention, such as intentional defect 216 shown in FIG. 2E, can be predetermined and thus known by patterning a recess opening, such as recess opening 306 in FIG. 3, at the location where the intentional defect is desired in the semiconductor structure. For example, if an intentional defect located at a corner region of the semiconductor structure is desired, a recess opening can be included at a corner region of mask layer 300, such as recess opening 306. As such, intentional defects can also be formed at various levels in the semiconductor structure of the invention by patterning recesses in the dielectric layers situated in the desired levels. Furthermore, by forming the recess, e.g., recess 206 shown in FIG. 2B, with a predetermined size and shape, the size and shape of the corresponding intentional defect, e.g., intentional defect 216 shown in FIG. 2E, situated in the semiconductor structure can also be predetermined, and thus known.

Referring to step 159 in FIG. 1 and semiconductor structure 258 in FIG. 2E, at step 159 of flowchart 100, the reliability of semiconductor structure 258 is characterized using the known characteristics, e.g., known location, size, and shape, of intentional defect 216. By way of background and referring to FIG. 2E of the invention, an intentional defect such as intentional defect 216 in dielectric layer 204 can result in extended or additional defects by undesirably spreading or “propagating” when the semiconductor structure is exposed to various temperatures and mechanical stresses during reliability testing, ultimately causing the semiconductor structure to fail. For example, intentional defect 216 in FIG. 2E can cause cracks within dielectric layer 204 that can propagate through dielectric layer 204 and through adjacent layers in the semiconductor structure, such as metal layers (not shown). Moreover, after the semiconductor structure is packaged, defects such as intentional defect 216 can cause delamination of dielectric layer 204 and etch stop layer 214 due to the high mechanical stresses which can result from chip package interaction (“CPI”).

As such, the reliability of a semiconductor structure can be characterized by determining the rate at which such a defect can propagate, i.e., the defect propagation rate, in a semiconductor structure. Since the location, size, and shape of each intentional defect included in the semiconductor structure of the invention is advantageously known, the defect propagation rate of an intentional defect that causes the semiconductor structure to fail during reliability testing can be determined. In contrast, in conventional semiconductor test structures, the characteristics, e.g., location, size, or shape, of the defects are not known or are very difficult to determine. For example, the defects in conventional semiconductor test structures are randomly situated and thus the locations of the defects can be difficult to determine. Consequently, once a defect having an unknown location propagates in conventional semiconductor test structures, the defect propagation rate of the defect cannot be determined.

Thus, the defect propagation rate data which can be advantageously determined from the semiconductor structure of the present invention through reliability testing can be used to accurately model the defect propagation rate in a semiconductor structure, for example, as a function of mechanical and thermal stresses applied to the semiconductor structure. Furthermore, such defect propagation rate data can also be used to model crack growth in a semiconductor structure which can result from, for example, exposure to moisture, various temperatures, and other conditions. Therefore, the present invention can be used to provide an accurate prediction of the life of a semiconductor structure.

In addition, by providing control over the location of the intentional defects situated in the semiconductor structure, the invention can advantageously control the distribution of defect propagation failures in a semiconductor structure, thus reducing the number of samples required to acquire sufficient defect propagation rate data. For example, intentional defects can be situated in areas of a semiconductor structure where defect propagation failures are less likely to occur, as well as in areas of the semiconductor structure where defects are more likely to occur, such as at the back-end-of-the-line (“BEOL”) or at an edge of the semiconductor structure. Furthermore, since the semiconductor structure of the invention allows control over the number and location of the intentional defects existing in the semiconductor structure, the invention can increase the frequency of defect propagation failures, thereby providing more defect propagation rate data over a shorter period of reliability testing than can be achieved with conventional semiconductor test structures. It is noted that the invention's method, as described above, results, among other things, in a more accurate reliability characterization of various semiconductor structures, thereby facilitating designing, and improving the design and fabrication of, semiconductor dies with improved reliability of longer life.

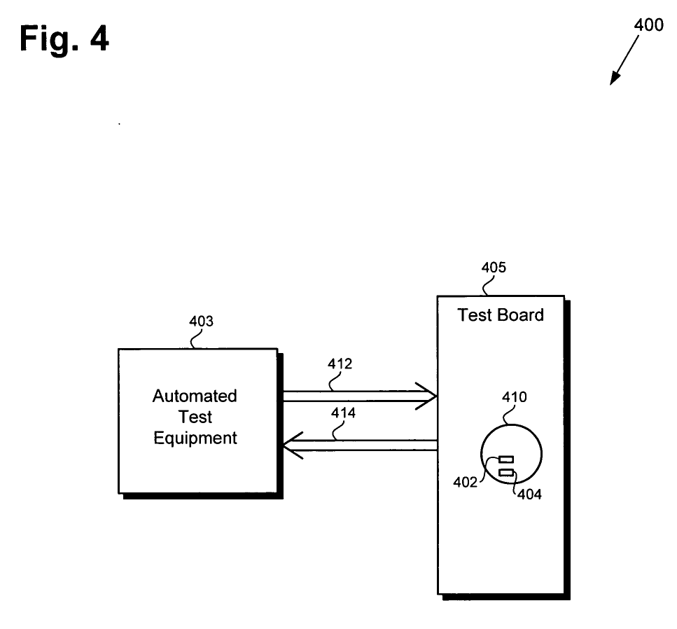

FIG. 4 illustrates a diagram of an exemplary test system including an exemplary wafer under test including multiple exemplary semiconductor structures in accordance with one embodiment of the present invention. Test system 400 includes automated (i.e. computerized) test equipment 403 and test board 405. Test board 405 includes and interfaces with wafer under test 410, which can include semiconductor structures 402 and 404. Wafer under test 410 can also include additional semiconductor structures (not shown in FIG. 4), which are similar to semiconductor structures 402 and 404. Semiconductor structures 402 and 404 can include intentional defects, such as intentional defect 216 shown in FIG. 2E, with known characteristics, e.g., known location, size, and shape, within semiconductor structures 402 and 404.

As shown in FIG. 4, test board 405 is coupled to automated test equipment 403 via buses 412 and 414. Test board 405 can include a number of interconnect traces (not shown in FIG. 4) to couple automated test equipment 403 to the appropriate contact pads on each semiconductor structure on wafer under test 410. Although in the present embodiment wafer under test 410 is mounted on test board 405, in other embodiments wafer under test 410 may not be mounted on test board 405, and may be connected directly to automated test equipment 403 via a number of probes and buses 412 and 414.

Test system 400 can be configured to perform a reliability test on each semiconductor structure on wafer under test 410 by applying, for example, mechanical stresses on each semiconductor structure and exposing each semiconductor structure to various temperatures. Test system 400 can also be configured to determine when a semiconductor structure on wafer under test 410 has failed due to the propagation of an intentional defect, such as intentional defect 216 in FIG. 2E. Thus, the known characteristics of the intentional defect, such as the known location of intentional defect 216, can then be used to determine a defect propagation rate as discussed above. As such, test system 400 can be utilized to accurately characterize the reliability of a semiconductor structure by determining the defect propagation rates of the invention's semiconductor structures. It is noted that the invention's method, as described above, and as implemented by various test systems, such as test system 400, results, among other things, in a more accurate reliability characterization of various semiconductor structures, thereby facilitating designing, and improving the design and fabrication of, semiconductor dies with improved reliability of longer life.

From the above description of the invention it is manifest that various techniques can be used for implementing the concepts of the present invention without departing from its scope. Moreover, while the invention has been described with specific reference to certain embodiments, a person of ordinary skill in the art would appreciate that changes can be made in form and detail without departing from the spirit and the scope of the invention. Thus, the described embodiments are to be considered in all respects as illustrative and not restrictive. It should also be understood that the invention is not limited to the particular embodiments described herein but is capable of many rearrangements, modifications, and substitutions without departing from the scope of the invention.

Thus, method and semiconductor structure for reliability characterization have been described.

1. A method for characterizing a reliability of a semiconductor structure, said method comprising steps of:
forming a recess in a first dielectric layer in said semiconductor structure;
filling said recess with a sacrificial material;
removing said sacrificial material to cause an intentional defect with known characteristics.

2. The method of claim 1 further comprising utilizing said known characteristics of said intentional defect to achieve a reliability characterization for said semiconductor structure.

3. The method of claim 2 further comprising fabricating a semiconductor die utilizing said reliability characterization.

4. The method of claim 1 wherein said known characteristics of said intentional defect include a known location of said intentional defect.

5. The method of claim 1 wherein said known characteristics of said intentional defect include a known size of said intentional defect.

6. The method of claim 1 wherein said known characteristics of said intentional defect include a known shape of said intentional defect.

7. The method of claim 1 further comprising a step of forming an etch stop layer over said dielectric layer and said sacrificial material prior to said step of removing said sacrificial layer.

8. The method of claim 1 wherein said step of removing said sacrificial material comprises decomposing said sacrificial material by performing a heating process.

9. The method of claim 1 further comprising a step of forming a second dielectric layer over said first dielectric layer and said sacrificial material after said step of filling said recess.

10. The method of claim 1 wherein said sacrificial material is a spin on decomposable polymer.

11. The method of claim 10 wherein a decomposition temperature of said decomposable polymer is greater than a formation temperature of said first dielectric layer.

12. A semiconductor structure for a reliability characterization, said semiconductor structure comprising:
a dielectric layer situated over a substrate;
an intentional defect with known characteristics situated in said dielectric layer;
wherein said intentional defect aids in achieving said reliability characterization of said semiconductor structure.

13. The semiconductor structure of claim 12 wherein said known characteristics of said intentional defect include a known location of said intentional defect.

14. The semiconductor structure of claim 12 wherein said known characteristics of said intentional defect include a known size of said intentional defect.

15. The semiconductor structure of claim 12 wherein said known characteristics of said intentional defect include a known shape of said intentional defect.

16. A test system for a reliability characterization of a semiconductor structure in a wafer under test, said semiconductor structure comprising:
a dielectric layer and an intentional defect with known characteristics situated in said dielectric layer;
wherein said intentional defect aids in achieving said reliability characterization of said semiconductor structure.

17. The test system of claim 16 wherein said reliability characterization is utilized to fabricate a semiconductor die.

18. The test system of claim 16 wherein said known characteristics of said intentional defect include a known location of said intentional defect.

19. The test system of claim 16 wherein said known characteristics of said intentional defect include a known size of said intentional defect.

20. The test system of claim 16 wherein said known characteristics of said intentional defect include a known shape of said intentional defect.
